(19) United States
(12) Patent Application Publication
(10) Pub. No.: US 2022/0406640 A1
(43) Pub. Date: Dec. 22, 2022

(54) METHODOLOGY FOR SUBSTRATE TO CATHODE PLANARITY AND CENTERING ALIGNMENT

(71) Applicant: Applied Materials, Inc., Santa Clara, CA (US)

(72) Inventors: Thomas BREZOCZKY, Los Gatos, CA (US); Kirankumar Neelasandra SAVANDAIAH, Bangalore (IN); Bhaskar PRASAD, Adityapur (IN); Nitin Bharadwaj SATYAVOLU, Kakinada (IN)

(21) Appl. No.: 17/354,441

(22) Filed: Jun. 22, 2021

(51) Int. Cl. H01L 21/68; H01L 21/683; H01L 21/677

(52) U.S. Cl. CPC H01L 21/68; H01L 21/6833; H01L 21/67706; H01L 21/67718; H01L 21/67766; H01L 21/67778

(57) ABSTRACT

A method and apparatus for aligning components within a processing module are described herein. The components include a substrate transfer device, a plurality of support chuck assemblies, and adjustable bushings disposed in the processing module. The substrate transfer device includes support arms with heads configured to passively correct the location of a substrate therein. The orientation of each of the support arms of the substrate transfer device is adjusted to align with each of the support chuck assemblies. The location of a process station is then adjusted to align with one of the support chuck assemblies by calibrating the adjustable bushings which correspond to each process station.

### BACKGROUND

### Field

The present disclosure relates to an apparatus and method of maintaining and correcting alignment of components within a substrate processing system. More particularly, the present disclosure relates to the use of adjustable structures and methods to enable alignment of carousel arms, processing stations, lift assemblies, and substrates.

### Description of the Related Art

Deposition and dry etch processes are used to form layers on, and remove all or a portion of one or more layers from, a substrate. For example, it is known to deposit thin metal and dielectric films on substrates, such as directly on a semiconductor substrate or on film layers already formed thereon, using a sputtering process, also known as physical vapor deposition or “PVD”. In PVD, a vacuum chamber holds a target and a support chuck assembly having a substrate thereon, and the target, composed of a metal or a dielectric, is negatively charged and exposed to an inert gas plasma to cause plasma formed gas ions to bombard the target and sputter material therefrom such that at least a portion of that material is deposited on the substrate. In the fabrication of semiconductor devices such as integrated circuits, PVD is commonly used to deposit materials, such as metal films, metal oxides and metal nitrides on a semiconductor substrate, or on film layers previously formed thereon. The deposited materials can then be further processed into metallic studs known as contacts or vias, or into lines used to interconnect active regions on or in the underlying semiconductor substrate. For the deposition of metal oxides and metal nitrides, an oxygen or nitrogen gas is added to the inert plasma gas, and the N or O atoms therein react with the sputtered metal to result in the metal oxide or metal nitride film being deposited on the substrate or a film layer thereon. PVD is also used to deposit layers, including non-metallic layers, which are used to define features in underlying film layers. For example, the PVD process is used to deposit patterning films, which are then patterned using a photoresist application and developing process, photolithography, and etching, to allow etching of an underlying film using an etchant to remove material exposed in openings in the patterning layer, as well as to deposit anti-reflective coatings, materials used to form hard masks and other useful materials.

Another method of forming a thin film on a substrate is commonly referred to as chemical vapor deposition, or “CVD”. In a CVD process, a substrate is loaded into a vacuum chamber, and one or more chemical precursors having the components of a thin film to be formed on the substrate are introduced into the vacuum chamber. Deposition of the thin film on the substrate, or on a layer thereon, occurs by one or more of a thermal reaction where the temperature of the substrate is sufficient to cause the precursor to decompose and leave behind one or more atoms of the thin film material to be deposited, by reaction of the chemical precursors with each other, at the substrate surface, over the substrate surface, or both, to form and leave on the substrate surface an atom or molecule of the thin film material to be deposited as a result of the reaction. To speed the reaction, or even initiate the reaction, a plasma or electromagnetic energy may be used to cause the material to be to be deposited on the substrate to be formed by reaction with the substrate surface, on the surface of a film layer thereon, over the substrate, or combinations thereof.

Dry etching, commonly used in semiconductor processing to form features in a substrate, or in one or more thin films on the substrate is typically a reactive ion etch process. Here, a plasma composed of an inert gas and one or more etching gases is formed in a vacuum chamber, and the material underlying a patterned mask layer is exposed to etching reactants in the plasma, while the substrate or support chuck assembly is negatively biased to also cause ions in the plasma to physically remove material of the underlying layer exposed through the openings in the mask layer. Etching radicals are simultaneously created from the etching gas in the plasma to chemically interact with and chemically etch the material of the underlying layer exposed through the openings in the mask layer.

Many thin film deposition and etch processes used in semiconductor and flat panel display production employ single substrate processing chambers that are attached to a mainframe of a cluster tool, wherein a single substrate is loaded into a dedicated vacuum process chamber having dedicated hardware therein to support the substrate during a process performed thereon. Misalignment of different components within the cluster tool and the single substrate processing chambers may cause poor deposition or etch results on the substrate. Misalignment between the different components stack and may sometimes cause substantial differences between simulated and actual processing results.

While the conventional cluster tool designs are suitable for processing substrates within the cluster tool, the inventors have found that current misalignment of different cluster tool components limits process reliability and repeatability. Misalignment may be between a substrate lift assembly and the individual process station or a robot transfer arm and the substrate lift assembly. A processing module of the cluster tool may also be tilted, such that one portion of the processing module is higher or lower than a second portion of the processing module. The substrate may also be misaligned with the robot transfer arm during picking up or positioning of the substrate onto each of the substrate lift assemblies.

Therefore, there is a need for a system and a method aligning components within a cluster tool that solves the problems described above.

### SUMMARY

The present disclosure generally relates to apparatus and methods for semiconductor processing. In one embodiment, a processing module for semiconductor processing is described. The processing module includes a transfer device disposed within a transfer region of the processing module and a support chuck assembly disposed at least partially within the transfer region. The transfer device includes a central hub having a central axis disposed therethrough and a plurality of support arms adjustably coupled to the central hub and configured to be rotated around the central axis. The support chuck assembly includes a support chuck having a substrate support surface, a pedestal shaft coupled to the support chuck, and a lift assembly coupled to the pedestal shaft. The lift assembly includes a module attachment plate, a static connection connecting the module attachment plate to a bottom surface of the processing module, and two or more adjustable connections disposed between the module attachment plate and the bottom surface of the processing module. The two or more adjustable connections are configured to be adjusted to change the orientation of the support chuck assembly relative to the transfer device.

In another embodiment, a processing module for semiconductor processing includes a plurality of walls defining a transfer region, a plurality of process stations coupled to one or more of the plurality of walls and in fluid communication with the transfer region, a support chuck assembly disposed at least partially within the transfer region, and two or more adjustable bushings disposed between a portion of each of the process stations and the one or more of the plurality of walls. The support chuck assembly includes a support chuck having a substrate support surface, a pedestal shaft coupled to the support chuck, and a lift assembly coupled to the pedestal shaft. The lift assembly includes a module attachment plate, a static connection connecting the module attachment plate to a lower wall of the plurality of walls, and two or more adjustable connections disposed between the module attachment plate and the lower wall. The two or more adjustable connections are configured to be adjusted to change the orientation of the support chuck assembly. The two or more adjustable bushings are configured to enable adjustment of the location of a first process station of the plurality of process stations relative to the support chuck assembly.

In another embodiment, a processing module for semiconductor processing includes a transfer device disposed within a transfer region of the processing module, a support chuck assembly disposed at least partially within the transfer region of the processing module, a plurality of process stations coupled to an upper surface of the processing module, and two or more adjustable bushings disposed between a portion of each of the process stations and the upper surface. The transfer device includes a central hub having a central axis disposed therethrough and a plurality of support arms adjustably coupled to the central hub and configured to be rotated around the central axis and carry a substrate. The support chuck assembly includes a support chuck having a substrate support surface, a pedestal shaft coupled to the support chuck, and a lift assembly coupled to the pedestal shaft. The lift assembly includes a module attachment plate, a static connection connecting the module attachment plate to a bottom surface of the processing module, and two or more adjustable connections disposed between the module attachment plate and the bottom surface of the processing module. The two or more adjustable connections are configured to be adjusted to change the orientation of the support chuck assembly. The plurality of process stations are in fluid communication with the transfer region. The adjustable bushings are configured to enable adjustment of the location of a first process station of the plurality of process stations relative to the support chuck assembly.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a plan view of a processing system that includes a processing module that includes process stations therein for processing substrates, according to one or more embodiments.

FIG. 2 is an isometric view of the processing module of FIG. 1 that includes a structural support assembly, according to one or more embodiments.

FIG. 3A is a cross sectional view of the processing module of FIG. 1 through a first plane, showing a configuration of a support chuck assembly in a process position of the processing module, according to one or more embodiments.

FIG. 3B is a partial sectional view of a portion of the processing module of FIG. 1 through a second plane, showing a configuration of a support chuck assembly in a transfer position below a process station of the processing module, according to one or more embodiments.

FIG. 3C is a partial cross-sectional view of the processing module of FIG. 1 through the second plane, showing an alternate configuration of the support chuck assembly illustrated in FIG. 3A lifted into a process position to form a sealed substrate process volume therewith, according to one or more embodiments.

FIG. 4A is a plan view of the processing module of FIG. 1, according to one or more embodiments.

FIG. 4B is a side view of the processing module of FIG. 4A, according to one or more embodiments.

FIG. 5A is a cross-sectional view of a lift assembly and support chuck assembly of FIGS. 3A-3C, according to one or more embodiments.

FIG. 5B is a plan view of the lift assembly of FIG. 5A, according to one or more embodiments.

FIG. 6A is a plan view of a central hub, according to one or more embodiments.

FIG. 6B is a plan view of a support arm, according to one or more embodiments.

FIG. 6C is a cross-sectional view of a head of the support arm, according to one or more embodiments.

FIG. 7A is a partial isometric view of a portion of the processing module body, according to one or more embodiments.

FIG. 7B is a cross-sectional view of a bushing assembly, according to one or more embodiments.

FIG. 8A is an isometric view of an insert of the bushing assembly, according to one or more embodiments.

FIG. 8B is a plan view of the insert of the bushing assembly, according to one or more embodiments.

FIG. 9A is an isometric view of a bushing of the bushing assembly, according to one or more embodiments.

FIG. 9B is a plan view of the bushing of the bushing assembly, according to one or more embodiments.

FIG. 10A is an isometric view of a wedge of the bushing assembly, according to one or more embodiments.

FIG. 10B is a plan view of the wedge of the bushing assembly, according to one or more embodiments.

FIG. 11 is an isometric view of a bushing alignment assembly, according to one or more embodiments.

FIG. 12 is a cross-sectional view of a process station within the processing module of FIGS. 3A-3C, according to one or more embodiments.

FIG. 13 is a method of aligning a carousel assembly and the lift assemblies of the processing module of FIGS. 3A-3C, according to one or more embodiments.

FIG. 14 is a second method of aligning the carousel assembly and the lift assemblies of the processing module of FIGS. 3A-3C, according to one or more embodiments.

FIGS. 15A-15D are process sectional plan views of the processing module during various operations of the method of FIG. 13, according to one or more embodiments.

FIG. 16 is a method of correcting alignment within the processing module of FIGS. 3A-3C, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to apparatus and methods for aligning components within a cluster tool. More specifically, the present disclosure is directed towards apparatus and methods for aligning transfer arms, lift assemblies, processing stations, and substrates within a processing module. The misalignment between each of the components may stack on top of each other to cause increased end misalignment between the substrate and each individual processing station within the processing module. Apparatus and methods which enable correction of the misalignment both before and during substrate processing are described.

It has been found that the overall processing modules within a cluster tool may be tilted or misaligned with a horizontal plane. The tilting of the overall processing module affects the relative angle of each of the components attached to and disposed within the processing module. Therefore, apparatus described herein assist in leveling the processing module using one or more leveling features disposed on the processing module and at least two adjustable legs. One portion of the processing module adjacent to the rest of the cluster tool may be held in place while the legs furthest from the cluster tool attachment are adjusted.

An adjustable substrate lift assembly is also described. The substrate lift assembly is configured to be tilted with respect to the processing module. At least one point on the substrate lift assembly is held in place. The substrate lift assembly is swiveled about the one still point and secured using two pins at other locations. The pins may be adjustable in length or may be tightened to change the orientation of the substrate lift assembly.

Adjustable substrate transfer arms are further described. The substrate transfer arms are connected to a central hub of a carousel assembly. Each of the substrate transfer arms may be adjusted during assembly of the processing module or during maintenance procedures. The substrate transfer arms are adjusted at the central hub and may be configured to align with each of the substrate lift assemblies. Aligning with the substrate lift assemblies enables the substrate to be lifted from and positioned onto the substrate lift assemblies while maintaining proper positioning. The head of each of the substrate transfer arms may also be configured to reduce error or misalignment caused by repeated lifting and positioning of the substrate. The error caused by lifting and positioning of the substrate is reduced by passively guiding the substrate to the center of a substrate support pocket within the head of the substrate transfer arm. The passive guiding is enables by using an angled inner wall outside of the substrate support surface.

The process station and the substrate lift assembly are aligned by adjusting the positioning of the process station. The process station is made adjustable in the x-y direction by one or more adjustable bushing assemblies. The bushing assemblies may be configured before a process station is positioned on the processing module. The bushing assemblies may be tested with a bushing alignment assembly. The bushing alignment assembly is positioned over an opening for one of the process stations before the process station is positioned therein. Once the bushing assemblies have been configured using the bushing alignment assembly, a process station is positioned over and within the opening. The bushing assemblies may be aligned so the center of the substrate lift assembly is positioned underneath the center of a target within the process station. Each of the process stations are configured to perform one or more processing operations on semiconductor substrates passing therethrough. The one or more processing operations include a PVD, a CVD, an ALD, or a dry etching process.

The substrate lift assemblies and the substrate transfer arms are adjusted after leveling of the processing module. The substrate lift assemblies and the substrate transfer arms are configured so that each of the substrate lift assemblies is aligned with each of the substrate transfer arms. After leveling of the processing module and aligning of the substrate lift assemblies with the substrate transfer arms, each of the processing stations are aligned with the substrate lift assemblies.

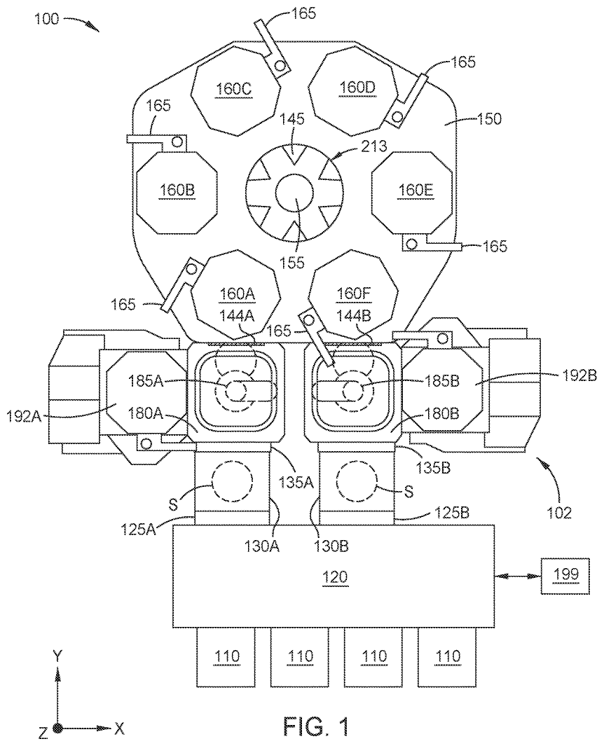

FIG. 1 is a plan view of a processing system 100 that includes processing module 150 that includes process stations 160A-160F therein for processing substrates, according to one or more embodiments. As shown in FIG. 1, the processing system 100 includes six process stations 160A-160F, which are accessible within the substrate processing module 150. A substrate may be sequentially moved along the circumference of an imaginary circle which intersects a central location of each of the process stations 160, such that a plurality of a processes are performed on the substrates. Each process station 160A-160F can be independently or similarly configured to enable a deposition process, for example a PVD, CVD, ALD (atomic layer deposition) or other type of deposition process, or an etching process. Each process station 160A-160F further is connected to a vacuum pump 165, for example a roughing pump, the output of which is connected to an exhaust duct (not shown), to reduce the pressure within the process stations 160A-160F to a sub-atmospheric pressure on the order of about 10⁻³ Torr.

The process stations 160a-160F are disposed around a central opening 213 and are positioned in a circular array around a central portion of the processing module 150. The central opening 213 is disposed through the middle of the processing module 150. The central opening 213 includes a transfer device 155 disposed therein. The transfer device 155 is configured to transfer a substrate between any one of the process stations 160A-160F within the processing module 150. The central opening 213 includes a transfer volume 145. The transfer device 155 is disposed within the transfer volume 145. The transfer volume 145 is the volume through which the substrates are transferred and includes an area directly below each of the process stations 160A-160F.

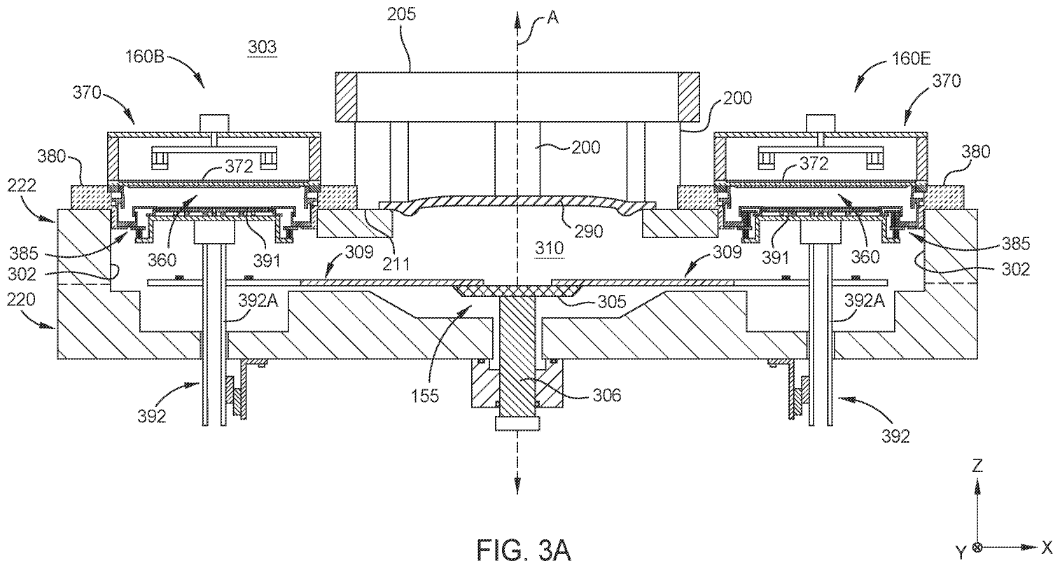

The processing system 100 further includes an intermediary section 102, which is coupled between the processing module 150 and a front end 120, and a system controller 199. As shown in FIG. 1, the intermediary section 102 includes a pair of loadlock chambers 130A, 130B and a pair of intermediate robot chambers 180A, 180B. Each of the loadlock chambers 130A, 130B is separately connected through a respective first valve 125A, 125B, at one side thereof to the front end 120, and through a respective second valve 135A, 135B, to one of the intermediate robot chambers 180A, 180B, respectively. During operation a front end robot (not shown) in the front end 120 moves a substrate therefrom into a loadlock chamber 130A or 130B, or removes a substrate from a loadlock chamber 130A, 130B. Then an intermediate robot 185A, 185B in one of the associated intermediate robot chambers 180A, 180B connected to an associated one of the loadlock chambers 130A, 130B moves a substrate from the loadlock chamber 130A or loadlock chamber 130B and into the corresponding intermediate robot chamber 180A, 180B. In one aspect, the intermediary section 102 also includes a preclean/degas chamber connected to an intermediate robot chamber 180, for example a preclean/degas chamber 192A connected to intermediate robot chamber 180A and a preclean/degas chamber 192B connected to intermediate robot chamber 180B. A substrate loaded into one of the loadlock chambers 130A, 130B from the front end 120 is moved, by the associated intermediate robot 185A or 185B, from the loadlock chamber 130A or 130B and into the preclean/degas chamber 192A or 192B. In the preclean/degas chambers 192A, 192B, the substrate is heated to volatilize any adsorbed moisture or other volatilizable materials therefrom, and is subjected to a plasma etch process whereby residual contaminant materials thereon are removed. Thereafter, the substrate is moved by the appropriate associated intermediate robot 185A or 185B back into the corresponding intermediate robot chamber 180A or 180B and thence onto a support chuck assembly 392 (FIG. 3A) at a process station in the substrate processing module 150, here process station 160A or 160F. In some embodiments, the substrate S is placed on a detachable portion (not shown) of the support chuck assembly 392, it remains thereon until all processing thereof in the processing module 150 is completed.

Here, each of the loadlock chamber 130A and the loadlock chamber 130B is connected to a vacuum pump (not shown), for example a roughing pump, the output of which is connected to an exhaust duct (not shown), to reduce the pressure within the loadlock chamber 130A, 130B to a sub-atmospheric pressure on the order of about 10⁻³ Torr or less. Each loadlock chamber 130A or 130B may be connected to a vacuum pump dedicated thereto, or a vacuum pump shared with one or more components within the processing system 100, or to a house exhaust other than a vacuum pump to reduce the pressure therein. In each case, a valve (not shown) can be provided on the loadlock chamber 130A, 130B exhaust to the pump or house exhaust to isolate, or substantially isolate, the pumping outlet of the loadlock chamber 130A, 130B connected to the vacuum pump or house exhaust from the interior volume of the loadlock chamber 130A, 130B when the first valve 125A or 125B respectively is open and the interior of the loadlock chamber 130A, 130B is exposed to atmospheric or ambient pressure conditions.

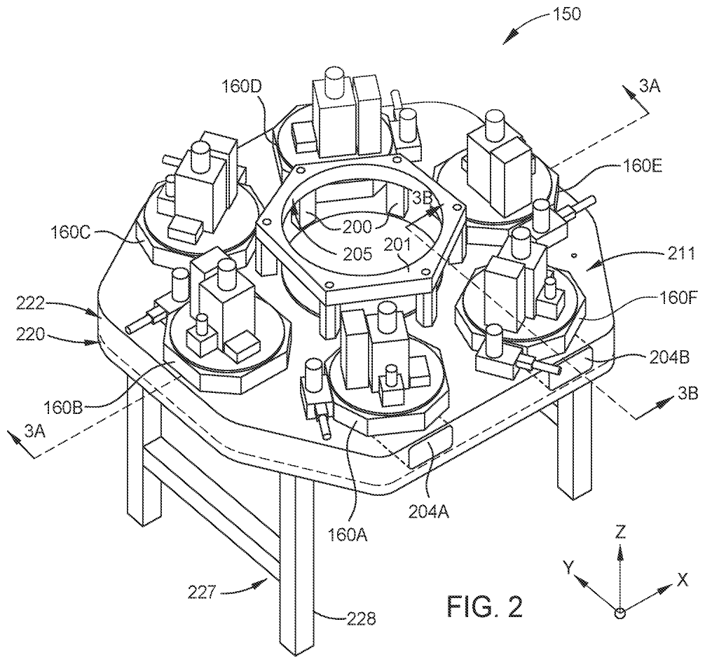

After the substrate has been processed, for example, in the, preclean/degas chamber 192B, the intermediate robot 185B removes the substrate from the preclean/degas chamber 192B. A process chamber valve 144B, which is disposed between the intermediate robot chamber 180B and the processing module 150, is opened to expose an opening 204B (FIGS. 2, 3A, and 3B) formed in a wall of the processing module 150, and the intermediate robot 185B moves the substrate through the opening 204B to a process station 160F of the processing module 150 where it is received for processing within one or more of the process stations of the processing module 150. In the same manner, a substrate can be moved from the front end 120 through the loadlock chamber 130A, to the preclean/degas chamber 192A, and then to the processing module 150 through a process chamber valve 144A (FIG. 2A) and an opening in the processing module 150 wall to be received at process station 160A. Alternatively, the process chamber valves 144A, 144B may be eliminated, and intermediate robot chambers 180A, 180B may be in direct uninterrupted fluid communication with the interior of the processing module 150.

Each of the loadlock chambers 130A, 130B and intermediate robot chambers 180A, 180B are configured to pass substrates from the front end 120 into the processing module 150, as well as from the processing module 150 and into the front end 120. Thus, with respect to the first intermediate robot chamber 180A, to remove a substrate positioned at process station 160A of the processing module 150, the process chamber valve 144A is opened, and the intermediate robot 185A removes the substrate from the process station 160A and moves it, through an open second valve 135A connected between the intermediate robot chamber 180A and the loadlock chamber 130A, to place the substrate in the loadlock chamber 130A. The end effector of the intermediate robot 185A on which the substrate was moved is retracted from the loadlock chamber 130A, the second valve 135A thereof is closed, and the interior volume of the loadlock chamber 130A is optionally isolated from the vacuum pump connected thereto. Then the first valve 125A connected to the loadlock chamber 130A is opened, and the front end 120 robot picks up the substrate in the loadlock chamber 130A and moves it to a storage location, such as a cassette or FOUP 110, located within or connected to a sidewall of, the front end 120. In a similar fashion, using the intermediate robot chamber 180B, the intermediate robot 185B, the loadlock chamber 130B and associated valves 135B and 125B thereof, a substrate can be moved from the process station 160F location to the front end 120.

During the movement of a substrate from the processing module 150 to the front end 120, a different substrate may be located within the preclean/degas chamber 192A, 192B connected to the intermediate robot chamber 180A, 180B through which the substrate being moved to the front end 120 passes. Because each preclean/degas chamber 192A, 192B is isolated from the intermediate robot chamber 180A, 180B to which it is attached by a valve, passage of a different substrate can be undertaken from the processing module 150 to the front end 120 without interfering with the processing of a substrate in the respective preclean/degas chambers 192A, 192B.

The system controller 199 controls activities and operating parameters of the automated components found in the processing system 100. In general, the bulk of the movement of a substrate through the processing system is performed using the various automated devices disclosed herein by use of commands sent by the system controller 199. The system controller 199 is a general use computer that is used to control one or more components found in the processing system 100. The system controller 199 is generally designed to facilitate the control and automation of one or more of the processing sequences disclosed herein and typically includes a central processing unit (CPU) (not shown), memory (not shown), and support circuits (or I/O) (not shown). Software instructions and data can be coded and stored within the memory (e.g., non-transitory computer readable medium) for instructing the CPU. A program (or computer instructions) readable by the processing unit within the system controller determines which tasks are performable in the processing system. For example, the non-transitory computer readable medium includes a program which when executed by the processing unit is configured to perform one or more of the methods described herein. Preferably, the program includes code to perform tasks relating to monitoring, execution and control of the movement, support, and/or positioning of a substrate along with the various process recipe tasks and various processing module process recipe steps being performed.

FIG. 2 is an isometric view of the processing module 150 of FIG. 1 that includes a structural support assembly 205, according to one or more embodiments. The processing module 150 includes a lower monolith 220 forming the lower portion or base of the processing module 150, and an upper monolith 222 that is sealed thereto and supported thereon. In some embodiments, the lower monolith 220 and the upper monolith 222 are welded, brazed or fused together by some desirable means to form a vacuum tight joint at the interface between the lower monolith 220 and the upper monolith 222. A lower supporting structure 227, which includes a support frame 228, is used to support the lower monolith 220 and the upper monolith 222 and position the processing module 150 at a desired vertical position above a floor (not shown).

To minimize the distortion of the processing module 150, the structural support assembly 205 is used to reduce the distortion of the lower monolith 220 and the upper monolith 222 and improve the parallelism of surfaces within the processing module 150 whether the processing module 150 is under vacuum or at ambient pressure. Here, to help ensure parallelism, the upper monolith 222 includes the structural support assembly 205 that includes an upper support element 201 and a plurality of mounting elements 200 that each have a first end that is coupled to an upper module surface 211. In some embodiments, the first end of the mounting elements 200 are coupled to the upper module surface 211 by bolting, welding, or even integrally forming the mounting elements 200 as part of the upper module surface 211. The array of mounting elements 200 are positioned on and coupled to the upper module surface 211 between each of the process stations 160A-160F. In some embodiments, the array of mounting elements each have a first end that is coupled to the upper module surface 211 at a radial position that is positioned on a radial direction that extends between two adjacent process station openings.

In some embodiments, the structural support assembly 205 generally comprises a toroidal shaped upper support element 201 that is coupled to a second end of each of the mounting elements 200 to minimize the deflection of the processing module 150. The upper support element 201 is coupled to each of the mounting elements 200 by bolting, welding, or even integrally forming the mounting elements 200 as part of the upper support element 201. The mounting elements 200 are configured to position the upper support element 201 a distance between about 150 mm and about 450 mm from the mounting surface (e.g., upper module surface 211). In some embodiments, the upper support element 201 and the mounting elements 200 are formed from the same material as the material used to form the upper monolith 222 and lower monolith 220 components, such as an aluminum material (e.g., 6061 Al). In some embodiments, the upper support element 201 and the mounting elements 200 are formed from a material that has a modulus of elasticity (E) that is greater than the material used to form the upper monolith 222 and lower monolith 220 components, such as an stainless steel material (e.g., 304 SST, 316 SST) and the upper monolith 222 and lower monolith 220 components are formed from an aluminum material.

### Process Station Hardware Examples

FIG. 3A is a cross sectional view of the processing module 150 of FIG. 1 through a first plane, along section line 3A-3A shown in FIG. 2, showing a configuration of support chuck assemblies 392 in a process position of the processing module 150 and disposed below two process stations 160B and 160E. In this configuration, the processing module 150 includes a transfer device 155 (FIG. 1) that includes a plurality of support arms 309 that are configured to transfer and deposit one or more substrates onto a substrate support surface 391A (FIG. 3B) of a support chuck 391. The substrate support surface 391A is formed on the support chuck 391 that is attached to a pedestal shaft 392A.

Each of the process stations 160B, 160E may be PVD process stations, such that the process stations 160B, 160E include a source assembly 370 and a PVD target 372. The source assembly 370, the PVD target 372, and the substrate support chuck 391 form at least a portion of a processing region 360 within each of the process stations 160B, 160E. While in the raised position a sealing assembly 385 forms a seal between the substrate support chuck 391 and the source assembly 370.

The transfer device 155 is disposed within a transfer region 310. The transfer region 310 is the area beneath each of the process stations 160A-160F and within the body of the processing module 150. The transfer device 155 is disposed radially inward of an inner processing module wall 302. The support arms 309 of the transfer device 155 extend from a central hub 305. The support arms 309 are configured to carry a substrate within the transfer region 310 and beneath each of the process stations 160A-160F. A central axis A passes through the center of the processing module 150 and the transfer device 155. The support arms 309 of the transfer device 155 rotate around the central axis A. The central axis A may be disposed through a rotation spindle 306 of the transfer device 155. The rotation spindle 306 is a shaft coupled to the central hub 305 and configured to rotate the transfer device 155. The rotation spindle 306 may be coupled to one or more actuators for rotating the central hub 305 and the support arms 309. The central axis A through the rotation spindle 306 may be referred to as a spindle axis.

FIG. 3B illustrates the support chuck assembly 392 that is positioned in a substrate receiving position or substrate transfer position. FIG. 3C illustrates the support chuck assembly 392 while it is positioned in a substrate processing position. The support chuck assembly 392 configurations illustrated in FIGS. 3A-3C illustrate a design in which a support chuck 391 of the support chuck assembly 392 remains attached to the pedestal lift assembly components such that it is dedicated to a single process station 160B, 160E, or 160F, and is limited to moving a substrate vertically, such as moving the substrate between the substrate receiving position and the processing position.

FIG. 3B is a partial sectional view of a portion of the processing module 150 of FIG. 1 through a second plane, along section line 3B-3B, showing a configuration of a support chuck assembly 392 in a transfer position below a process station 160F of the processing module 150, according to one or more embodiments.

The support chuck assembly 392 includes a heater power source 398, an electrostatic chuck power source 399 and a backside gas source 397. The heater power source 398 and/or electrostatic chuck power source 399 are each electrically coupled to one or more electrical elements formed within the substrate support chuck 391. In this configuration, the body of the support chuck 391 includes one or more resistive heating elements embedded therein. The resistive heating elements are disposed within the body of the substrate support chuck 391 and are in electrical communication with the output connections of the heater power source 398. The one or more chucking electrodes disposed within the body of the substrate support chuck 391 are in electrical communication with the electrostatic chuck power supply 399. In one example, three wires that are coupled to the output of the heater power source 398 and two wires that are coupled to the electrostatic chuck power source 399 are provided through pedestal shaft 392A so that they can be separately connected to their respective electrical elements.

During processing, when the substrate and support chuck assembly 392 are positioned in a processing position below the source assembly 370, a portion of the support chuck assembly 392, or component attached thereto, e.g., a sealing assembly 385, includes a sealing surface 396 that is adapted to form a “seal” with a portion of a liner 382 of the process station 160F so as to substantially fluidly isolate the processing region 360 from the transfer region 310. In some embodiments, the seal between the liner assembly 382 and the sealing assembly 385 is created by the physical contact created between a surface of the sealing surface 396 and a surface of the portion of the liner 382. In some lower temperature applications, the seal is formed by use of wiper seal, u-cup seal or an O-ring (not shown) that is positioned at the interface between the sealing surface 396 of the support chuck assembly 392 and the surface of the portion of the liner 382. Also, in some high temperature applications, such as at temperatures greater than 200° C., the seal is formed by metal-to-metal, or metal-to-ceramic contact formed at the interface between the portion of the sealing surface 396 of the support chuck assembly 392 and the portion of the liner 382.

Referring to FIG. 3B, the plurality of support arms 309 are configured to pick-up and deposit one or more substrates onto the substrate support surface 391A of a support chuck assembly 392. In one embodiment, the transfer device 155 includes a lift mechanism (not show) that is configured to at least raise and lower the plurality of support arms 309 attached thereto from a transfer position to a substrate drop off position, which is below the transfer position. A similar robot arm configuration, or end of a robotic arm, as the support arm 309 may also be utilized as part of the end effector of the transfer device 155 to pick-up and drop-off substrates on the substrate support surface 391A of the substrate support chuck 391.

The processing regions 360 of each process station 160A-160F can be separately and selectively isolated by controlling the movement and position of the support chuck assembly 392 at each process station 160A-160F based on commands sent from the system controller 199 (FIG. 1).

The source assembly 370 forms a portion of each of the process stations 160A-160F. The source assembly 370 includes the target 372, a magnetron assembly 371, source assembly walls 373, and a sputtering power supply 375. In this configuration, a processing surface 372A of the PVD target 372 generally defines at least a portion of the upper portion of the process stations 160A-160F. The magnetron assembly 371 includes a magnetron region 379 in which the magnetron 371A is rotated by use of a magnetron rotation motor 376 during processing. The target 372 and magnetron assembly 371 are typically cooled by the delivery of a cooling fluid (e.g., DI water) to the magnetron region 379 from a fluid recirculation device. The magnetron 371A includes a plurality of magnets 371B that are configured to generate magnetic fields that extend below the processing surface 372A of the target 372 to promote a sputtering process performed in the processing region 360 during a PVD deposition process.

In alternate configurations of the process stations 160F, which are adapted to perform CVD, PECVD, ALD, PEALD, etch, or thermal processes, the source assembly 370 includes different hardware components. In one example, the source assembly 370 of a process station that is adapted to perform a CVD deposition process, a PECVD deposition process or an etch process includes a gas distribution plate, or showerhead, that is configured to deliver a precursor gas or etching gas into the processing region 360 and across a surface of a substrate disposed within the process station 160F during processing. Generally, a showerhead, or gas distribution plate, includes a metal, quartz or ceramic plate that has a plurality of holes (e.g., >100 holes) formed therein to restrict and thus allow an even distribution of a gas to flow from an upstream side of the showerhead to a downstream side of the showerhead, which is positioned adjacent to the processing region 360 of a processing station 160A-160F during processing. The gas (e.g., precursor gas or etching gas) is delivered to the upstream side of the showerhead and through the showerhead by a precursor gas source (not shown) typically disposed outside of the processing system 100. In this configuration of the source assembly 370, the one or more processing surfaces that define at least a portion of the processing region 360 is the lower surface of the gas distribution plate, or showerhead (e.g., surfaces that contact the processing region). In this configuration, the magnetron assembly 371 and target are not used, and the sputtering power supply 375 can be replaced with an RF power supply that is configured to bias the gas distribution plate.

The processing region 360 is further formed by a process kit assembly 380. The process kit assembly 380 includes one or more liners 382 and a processing region body. In some embodiments (not shown), the sealing assembly 385 may be coupled to the process kit assembly 380. A process gas supply 389 and an exhaust pump 365 are further coupled to the process kit assembly 380 and in fluid communication with the processing region 360, such that the process gas supply 389 supplies process gases to the processing region 360 and the exhaust pump 365 evacuates and pumps down the processing region 360.

The central opening 213 of FIG. 1 is covered with a central opening lid 290. The central opening lid 290 is coupled to the upper module surface 211 of the processing module 150. The central opening lid 290 separates the transfer region 310 from an outer area 303, wherein the outer area 303 is an outside volume (i.e., external environment) surrounding the processing module 150. The central opening lid 290 and the process stations 160A-160F fluidly seal the processing module 150. Therefore, the transfer region 310 may be pumped down to a vacuum by a transfer volume pump 354. A transfer volume gas supply 355 may also be coupled to the transfer region 310. The transfer volume gas supply 355 may supply an inert gas or other process gas to the transfer region 310.

A lift assembly axis B is disposed through the center of the support chuck assembly 392. The lift assembly axis B is disposed parallel to the direction of travel of the support chuck 391 during raising and lowering of the support chuck 391. The lift assembly axis B is centered within the support chuck assembly 392, such that a substrate S placed on the center of the substrate support surface 391 is centered along the lift assembly axis B.

The head of each of the support arms 309 includes a transfer arm axis C. The transfer arm axis C is the central axis of the head of each of the support arms 309. The transfer arm axis C passes through the center of a pocket formed by the head of the support arms 309 for carrying a substrate S. When the support arms 309 are centered above one of the support chuck assemblies 392, a substrate may be loaded or unloaded onto the head of the support arms 309. While the substrate S is being loaded or unloaded from the support arms 309 onto the support chuck assembly 392, the transfer arm axis C and the lift assembly axis B are aligned or nearly aligned for at least a portion of the substrate S transfer.

Each of the source assemblies 370 includes a source axis D. The source axis D is the central axis through the source assembly 370. The source axis D passes through the center of the magnetron assembly 371, the magnetron 371A, and the PVD target 372. The source axis D passes through the center of the process stations 160F and is described as a process station axis, a mini environment axis, or a Pod axis. The source axis D and the lift assembly axis B are preferably aligned during processing of the substrate within the processing region 360. Misalignment of the source axis D and the lift assembly axis B may cause non-uniform deposition or etch on the substrate S. Misalignment of the source axis D and the lift assembly axis B may be caused by tilting or x-y offset of one of the support chuck assembly 392 or the source assembly 370.

As previously disclosed, FIG. 3C is a partial cross-sectional view of the processing module 140 of FIG. 1, along the section line 3B-3B, showing the support chuck assembly 392 illustrated in FIG. 3B lifted into a process position to form a sealed substrate process volume therewith, according to one or more embodiments. When the support chuck assembly 392 is raised to the process position, the sealing surface 396 of the support chuck assembly 392 and the sealing surface of the liner assembly 382 are pressed together to form a seal between the transfer region 310 and the processing region 360. The seal fluidly isolates the processing region 360 from the transfer region 310, and a process is performed on a substrate S within the processing region 360. The support chuck assembly 392 may also be raised to fluidly isolate the transfer region 310 from the outer area 303 when one of the process stations 160A-160F are removed for maintenance or replacement.

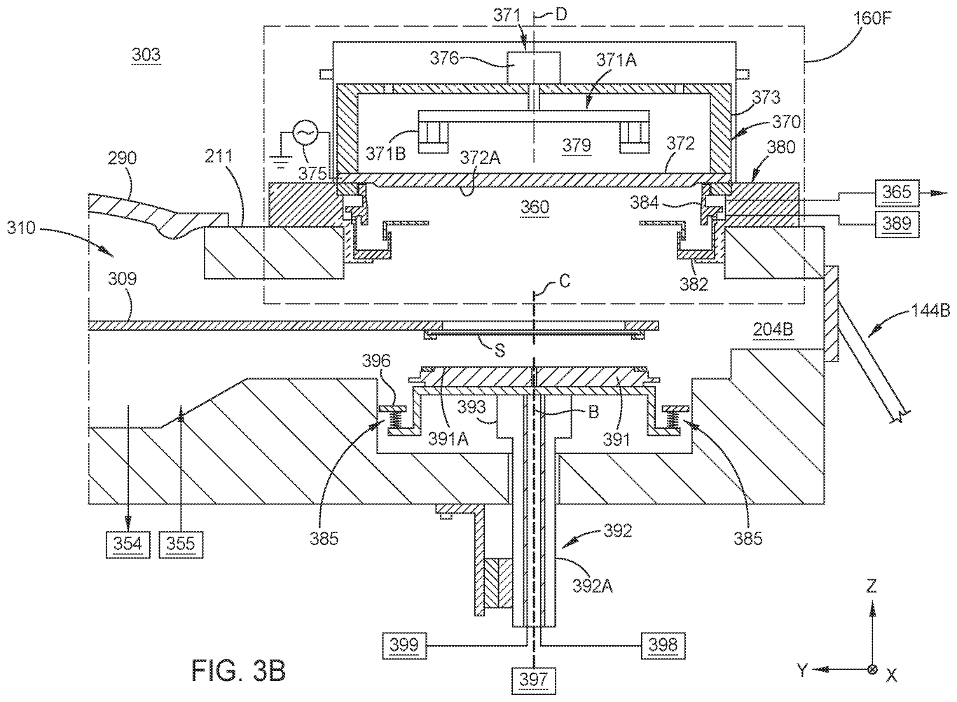

FIG. 4A is a plan view of the processing module 150 of FIG. 1, according to one or more embodiments. FIG. 4B is a side view of the processing module in FIG. 4A along line 4B-4B. The processing module 150 is split across a plane E. The plane E passes through the central axis A of the processing module 150. A first process station 160a, a second process station 160b, and a third process station 160c are on a first side of the plane E. A fourth process station 160d, a fifth process station 160e, and a sixth process station 160f are on a second side of the plane E opposite the first side. A plane F passes through an edge of the processing module 150. The plane F is parallel to the openings 204A, 204B through the processing module 150. The plane F may represent the connection of the processing module 150 to other components of the processing system 100, such as the intermediate robot chambers 180A, 180B.

A leveling feature 402 is disposed on the upper module surface 211. The leveling feature 402 is disposed on an end of the upper module surface 211 opposite the plane F. In some embodiments, the leveling feature 402 is positioned adjacent to an edge of the upper module surface 211 opposite the plane F. The leveling feature 402 is disposed between the third process station 160c and the fourth process station 160d. The leveling feature 402 is a machined groove within the upper module surface 211 configured to hold a level or orientation sensing device. The machined groove has a planar bottom surface configured to support the level or orientation sensing device.

The support frame 228 of the lower supporting structure 227 further includes a plurality of support legs 404a-404c. Each of the support legs 404a-404c is coupled to a bottom of the processing module 150. A first support leg 404a is disposed between the first process station 160a and the sixth process station 160f and adjacent to the plane F and the openings 204a, 204b. The first support leg 404a may be adjustable in height or may be maintained at a rigid height. As shown in FIG. 4B, the first support leg 404a is connected to the processing module 150 at a first support component 412a. The first support component 412a includes a pivot member 414. The pivot member 414 may contain a ball and socket apparatus connecting the first support component 412a and the bottom of the processing module 150. The first support component 412a enables the orientation of the processing module 150 to be changed with respect to the first support leg 404a without bending or inducing unintentional strain on the first support component 412a or the first support leg 404a.

In some embodiment, the pivot member 414 is a hinge assembly, such that a first hinge plate is coupled to the processing module, a second hinge plate is coupled to the first support leg 404a, and a pin couples the first hinge plate and the second hinge plate (not shown). Other embodiments of the pivot member 414 are envisioned.

A second support leg 404b and a third support leg 404c are disposed on the opposite side of the bottom surface of the processing module 150 from the first support leg 404a. The second support leg 404b and the third support leg 404c are each coupled to the bottom surface of the processing module 150 using a second support component 412b, such that a second support component 412b is disposed on top of the second support leg 404b and another second support component 412b is disposed on top of the third support leg 404c. The second support components 412b may similarly include a pivot member 414, similar to the pivot member 414 of the first support component 412a. The second support components 412b are also adjustable in height and may be used to raise or lower a portion of the processing module 150. The second support components 412b include an actuator and may be pneumatically actuated, hydraulically actuated, or mechanically actuated. The second support leg 404b and the third support leg 404c are configured to be extended or retracted at the second support components 412b to level the entire processing module 150. Positioning a pivot member 414 at the top of the second support leg 404b and the third support leg 404c reduces strain accumulated within the second support leg 404b, the third support leg 404c, and the processing module 150 while the orientation of the processing module 150 is being adjusted.

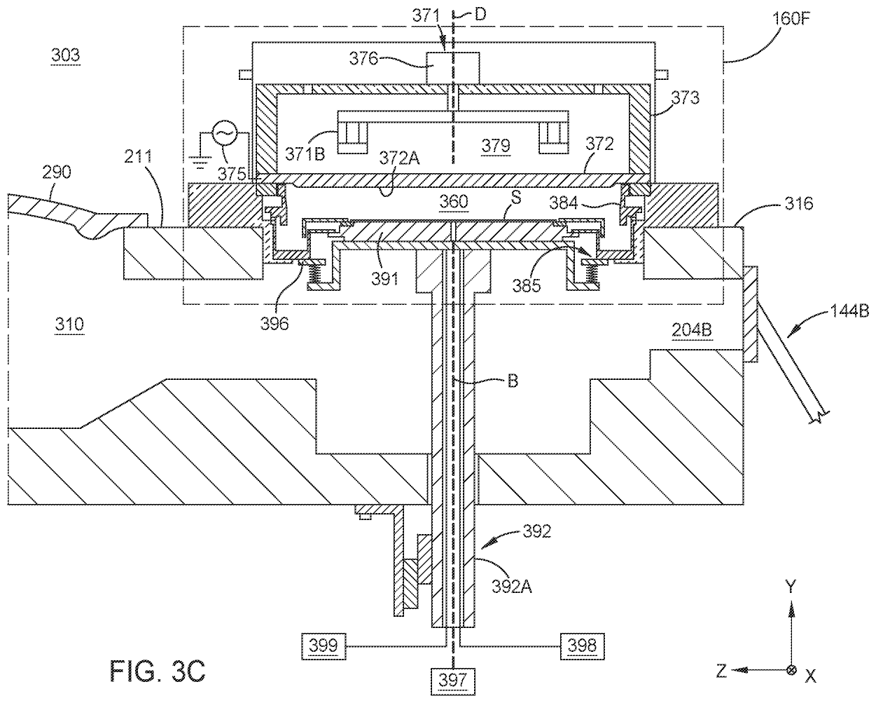

FIG. 5A is a cross-sectional view of a lift assembly 502 coupled to the support chuck assembly 392 of FIGS. 3A-3C. The lift assembly 502 is configured to enable adjustment of the orientation of the support chuck assembly 392. The support chuck assembly 392 is coupled to the lift assembly 502 at a support ledge 515. The support ledge 515 is coupled to a bottom end of the pedestal shaft 392A of the support chuck assembly 392. The support ledge 515 is connected to an actuator assembly 524. The actuator assembly 524 may be an actuator, such as a linear actuator or a combination of actuators, such as a linear actuator for raising/lowering the support chuck assembly 392 and a rotary actuator for rotating the support chuck assembly 392 about the lift assembly axis B. The actuator assembly 524 is coupled to an actuator support 522. The actuator support 522 is coupled to a module attachment plate 504.

The module attachment plate 504 is configured to couple the lift assembly 502 to the processing module 150. The module attachment plate 504 is configured to be coupled to a bottom surface of the processing module 150. The module attachment plate 504 is coupled to the processing module 150 using a static connection 508 and two or more adjustable connections 510a, 510b. The static connection 508 is disposed on one side of the module attachment plate 504 and acts as a pivot point around which the lift assembly 502 is rotated, while the adjustable connections 510a, 510b (FIG. 5B) are adjusted to change the tilt angle of the lift assembly 502 and the support chuck assembly 392.

At least part of the static connection 508 is configured to be disposed within the bottom surface of the processing module 150 or is secured to the bottom surface of the processing module 150. The static connection 508 may include a ball and socket 509, such that while the body of the static connection 508 is held in place by the processing module 150, the module attachment plate 504 and the lift assembly 502 are free to move around the static connection 508. The ball and socket 509 includes a pivot point P disposed therein for the lift assembly 502.

Each of the two or more adjustable connections 510a, 510b include a spring 519 disposed between the module attachment plate 504 and the processing module 150 to maintain a spring force separating the module attachment plate 504 and the processing module 150. A separation rod 511 is disposed through the module attachment plate 504 and configured to have an adjustable upper length 521 disposed over the top side of the module attachment plate 504. The spring 519 wraps around the separation rod 511, such that the upper length 521 of the separation rod 511 is disposed within the spring 519.

The separation rod 511 is disposed through the module attachment plate 504, such that there is a lower length 517 disposed below the module attachment plate 504. While adjusting the orientation of the lift assembly 502, the amount of the separation rod 511 which constitutes the upper length 521 is adjusted. When the upper length 521 of the separation rod 511 is increased, the lower length 517 is decreased. Alternatively, when the upper length 521 of the separation rod 511 is decreased, the lower length 517 is increased. The separation rod 511 may be threaded through the module attachment plate 504, such that turning the separation rod 511 can change the relative length of the upper length 521 and the lower length 517. After adjusting the separation rod 511 to have the desired upper length 521 and/or lower length 517, the separation rod 511 is secured using a lock 513. The lock 513 may be a fastener, a clasp, or a clamp. The lock 513 is configured to hold the separation rod 511 in place relative to the module attachment plate 504. The threaded separation rod 511 enables the upper length 521 to be fine tuned as needed without steps. A spherical washer pair 523 is disposed around each of the threaded separation rods 511. The spherical washer pairs 523 enable rotation of the connections 510a, 510b with respect to the module attachment plate 504. Therefore, the spherical washer pairs 523 enable rotation of the lift assembly 502 with respect to the processing module 150 without accumulating unnecessary strain within the separation rods 511, the module attachment plate 504, or the processing module 150.

In some embodiments, the spring 519 is separated from the separation rod 511 and disposed adjacent to the separation rod 511 or there may be multiple springs distributed around each separation rod 511. The adjustable connections 510a, 510b may alternatively comprise other connection types.

The pedestal shaft 392A is disposed through an opening 506 within the module attachment plate 504. The opening 506 is formed by an inner sidewall 516. The inner sidewall 516 has a radius larger than the radius of the pedestal shaft 392A. At least a portion of the pedestal shaft 392A is surrounded by a set of bellows 512. The bellows 512 are coupled to the bottom surface of the processing module 150 at a bellows sealing attachment 514. The bellows sealing attachment 514 forms a seal between the processing module 150 and the bellows 512 to prevent gases from entering or leaving the transfer region 310 to the outer area 303. The bellows 512 are coupled to the support ledge 515 at the bottom end thereof. The bellows 512 may expand and contract as the pedestal shaft 392A is raised and lowered.

FIG. 5B is a plan view of the lift assembly 502, according to one or more embodiments. As shown in FIG. 5B, the static connection 508 and two or more adjustable connections 510a, 510b enable rotation of the module attachment plate 504 about a first axis G and a second axis H. The first axis G intersects the static connection 508. The second axis H is disposed through the static connection 508 as through the center of the opening 506 and perpendicular to the first axis G. When both of the first adjustable connection 510a and the second adjustable connection 510b are adjusted by the same amount, the lift assembly 502 is rotated about the axis G. When one of the first adjustable connection 510a or the second adjustable connection 510b is adjusted by a different amount than the other of the first adjustable connection 510a or the second adjustable connection 510b, the lift assembly 502 is rotated about the axis H. A shaft opening 505 is disposed through the bellows sealing attachment 514. One or more supports 520 may be coupled to the bellows sealing attachment 514 to hold the bellows sealing attachment 514 in place relative to the module attachment plate 504.

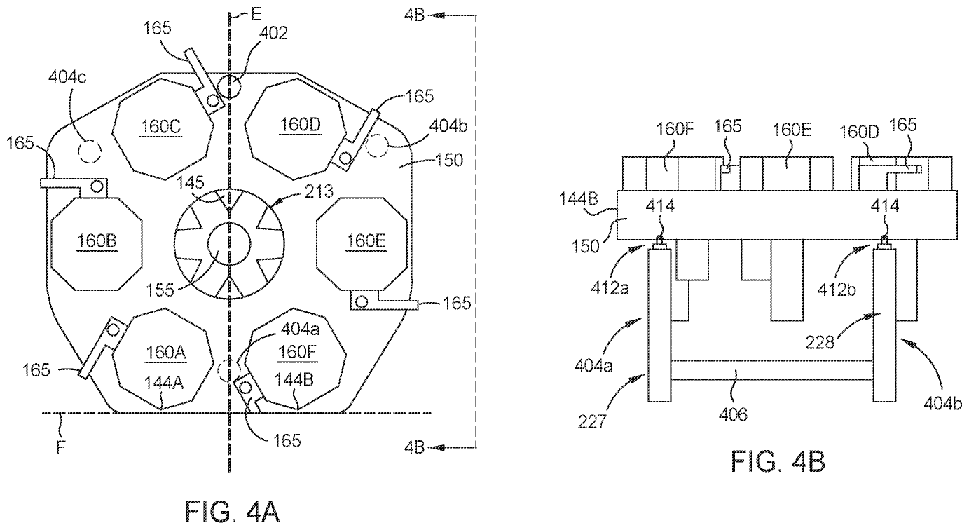

FIG. 6A is a plan view of a central hub 305, according to one or more embodiments. The central hub 305 is configured to support a plurality of support arms 309. The support arms 309 are adjustably mounted on the central hub 305 at one or more regions 606 of the central hub 305. One or more openings 602 are disposed through each of the regions 606. The openings 602 are configured to align with openings 618 disposed through a base 616 of one of the support arms 309 (FIG. 6B).

Through holes 608 are used for assembling the central hub 305 to a spacer (not shown), while optional through holes 610 allow assembly to other components, such as an actuator (not shown) or the rotation spindle 306 (FIG. 3A). Each of the regions 606 are disposed between the outer circumference 614 of the central hub 305 and an inner radius 612. The inner radius 612 is disposed outward from the holes 608 and through holes 610.

FIG. 6B is a plan view of the support arm 309, according to one or more embodiments. The support arm 309 includes a head 624, an arm shaft 622, and a base 616. The arm shaft 622 couples the head 624 and the base 616. The base 616 is configured to be coupled to one of the regions 606 of the central hub 305. The openings 618 through the base 616 are slits through the base 616. The openings 618 extend along a portion of the length of the support arm 309 to enable the support arm 309 to be lengthened or shortened as desired. One or more fasteners 609 (FIG. 6A) may be threaded through each of the openings 618 and the openings 602 of the regions 606 to secure the support arms 309 to the central hub 305. The positioning of each of the support arms 309 is adjustable and enables the orientation of each of the support arms 309 to be adjusted relative to the central hub 305.

The head 624 includes a first grasper 626 and a second grasper 628. The first grasper 616 and the second grasper 618 are configured to support portions of a substrate, such as the substrate S. The first grasper 616 and the second grasper 618 are disposed on opposite sides of the head 614.

FIG. 6C is a cross-sectional view of the head 624 of the support arm 309. The first grasper 626 and the second grasper 628 are disposed vertically offset from and below the arm shaft 622. A substrate support pocket 625 is formed by the first grasper 626, the second grasper 628, and a ceiling 630 of the head 614. The ceiling 630 is disposed over the first grasper 626 and the second grasper 628.

The first grasper 626 includes a first ledge 635. The second grasper 628 includes a second ledge 634. The first ledge 635 and the second ledge 634 are parallel to one another and disposed within the same plane. The first ledge 635 and the second ledge 634 are planar surfaces. A first angled surface 633 connects the first ledge 635 to the ceiling 630. A second angled surface 632 connects the second ledge 634 to the ceiling 630. Each of the first angled surface 633 and the second angled surface 632 are connected to the first and second ledges 635, 634 and disposed at an angle ϕ with respect to the first and second ledges 635, 634. The angle ϕ is about 110 degrees to about 135 degrees, such as about 115 degrees to about 125 degrees, such as about 120 degrees.

The first and second angled surfaces 633, 632 enable the substrate S to be passively slid back into place if the substrate S is misaligned during substrate transfer onto the support arm 309. A pocket diameter Po is defined as the distance from the outer edge of the first ledge 635 to the outer edge of the second ledge 634 across a diameter of the substrate support pocket 625. The pocket diameter Po is configured to be larger than a diameter of a substrate S disposed within the substrate support pocket 625. The pocket diameter P_{D} may be less than 1 mm larger than the diameter of the substrate S when processes are used where substrate placement has tighter constraints. For high temperature processes, the pocket diameter P_{D} is about 1 mm to about 2 mm larger than the diameter of the substrate S to enable substrate S expansion in the pocket. The angle ϕ is chosen to prevent the substrate S from being wedged into the substrate support pocket 625 and being damaged during substrate S expansion. In some embodiments, the pocket diameter P_{D} is about 301 mm to about 302 mm. A surface roughness of one or a combination of the first ledge 635, the second ledge 634, the first angled surface 633, and the second angled surface 632 is less than a Ra of about 15 pin, such as less than a Ra of about 10 pin, such as less than a Ra of about 8 pin. The surface roughness further reduces particle generation between the substrate and the substrate support pocket 625 during transfer.

An opening 636 is disposed between the first grasper 626 and the second grasper 628. The opening 636 enables lift pins or other lifting components to contact a bottom surface of the substrate S and remove the substrate S from the support arms 309. A circumference of the opening 636 is formed by one or more walls 642 disposed on the inner portion of the first grasper 626 and the second grasper 628. The walls 642 are coupled to both the first ledge 635 and the second ledge 634 by an intermediate angled surface 638 and a lower stepped surface 640.

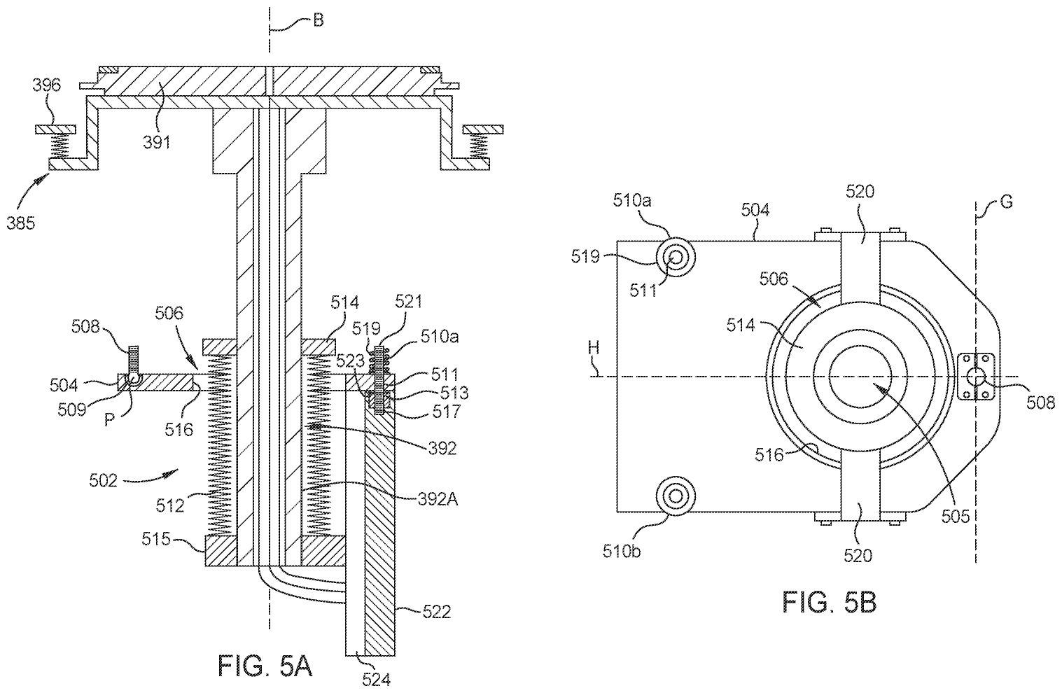

FIG. 7A is a partial isometric view of a portion of the processing module 150 body. Each of the process stations 160A-160F (FIG. 1) are positioned within a process station opening 702 formed through the upper module surface 211. The process station opening 702 fluidly connects the upper module surface 211 and the transfer region 310. An opening wall 704 is disposed between the upper module surface 211 and the transfer region 310. Two or more adjustable bushings 706 (two shown) are disposed around each of the process station openings 702. The adjustable bushings 706 are used to secure one of the process stations 160A-160F to the processing module 150. The adjustable bushings 706 further enable the position of the processing module 150 to be adjusted. The adjustable bushings 706 are calibrated before placement of the process stations 160A-160F onto the processing module 150. At least two adjustable bushings 706 are utilized to enable repeatable placement of a process station 160A into the process station opening 702. Two or more adjustable bushings 706 are utilized for each process station 160A-160F, such as three or more adjustable bushings 706, such as three adjustable bushings 706. When at least three bushings 706 are utilized, the alignment methods are performed with a greater degree of accuracy by generating three or more adjustable points.

FIG. 7B is a cross-sectional view of a bushing assembly 706, according to one or more embodiments. The bushing assembly 706 may be individually calibrated to align a process station 160A-160F with a support chuck 392 disposed within the processing module 150. The bushing assembly 706 includes an insert 710, a bushing 712, and two or more wedges 714. The bushing 712 and the two or more wedges 714 are disposed inside of the insert 710. The insert 710 is disposed inside of a cavity 708 formed in the upper module surface 211.

The location of the bushing 712 within the insert 710 is adjusted by loosening or tightening each of the two or more wedges 714 relative to a bottom insert surface 722. The two or more wedges 714 are tightened using a screw or other fastener 724. Each fastener 724 is disposed through one of the wedges 714 and the bottom insert surface 722 to change the displacement of the wedge 714 with respect to the bottom insert surface 722. When the wedge 714 is tightened to be closer to the bottom insert surface 722, the bushing 712 is pushed further from a sidewall of the insert 710.

The insert 710 is coupled to the processing module 150 using a fastener 718, such as a screw or a bolt. The fastener 718 is disposed through an insert fastener opening 720 and couples the insert 710 to a bottom surface of the cavity 708. The bottom surface of the cavity 708 includes a fastener hole 716 configured to receive the bottom end of the fastener 718.

The bushing 712 includes a bushing opening 726 disposed therein. The bushing opening 726 is configured to enable a pin or other securing member to be inserted therein from the process stations 160A-160F. Once the pin or other securing member is inserted into the bushing opening 727, the bushing 712 locks the process station 160A-160F in place in an x-y direction relative to the processing module 150.

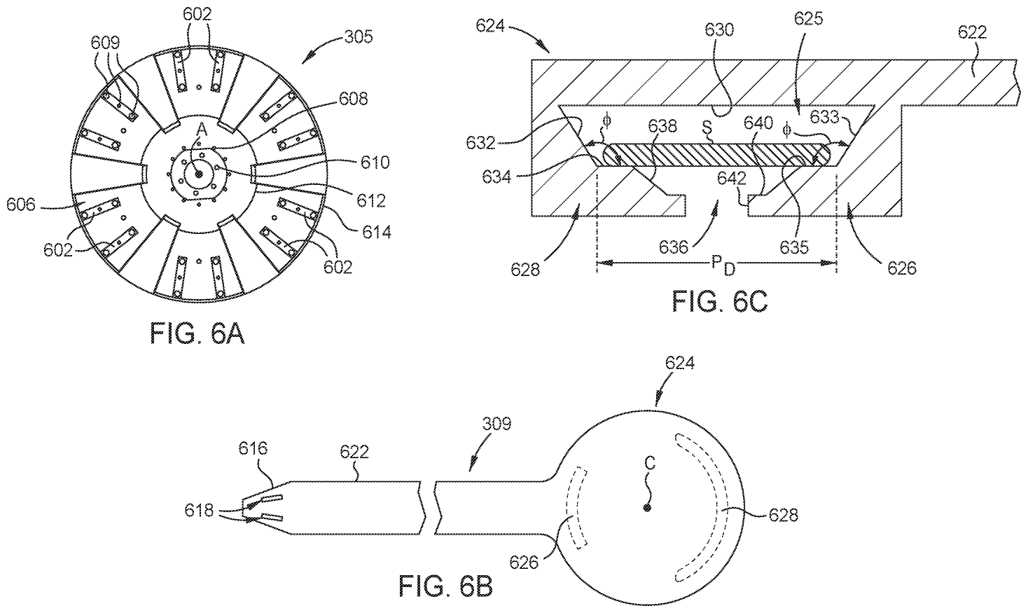

FIG. 8A is an isometric view of the insert 710 of the bushing assembly 706, according to one or more embodiments. The insert 710 includes a bottom surface 804, a top surface 806, and an outer sidewall 802 disposed between the bottom surface 804 and the top surface 806. A pocket 811 is disposed within the top surface 806 and towards the bottom surface 804. The pocket 811 includes a cylindrical sidewall 810. The cylindrical sidewall 810 is disposed perpendicular to the top surface 806 and/or the bottom surface 804. The cylindrical sidewall 810 is broken into several sections by a plurality of grooves 808 formed in the cylindrical sidewall 810. At least a portion of each of the grooves 808 is disposed at an angle different from the cylindrical sidewall 810, such that the pocket 811 narrows as the groove 808 extends away from the top surface 806. The angle of the grooves 808 enables the wedges 714 to adjust the position of the bushing 712.

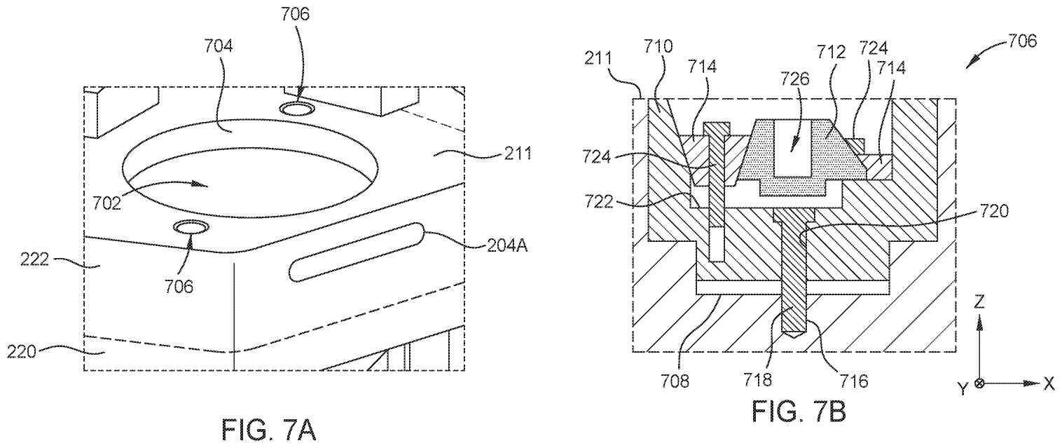

The bottom insert surface 722 is disposed on the bottom of the pocket 811. Connected to each of the sections of the cylindrical sidewall 810 is a shelf 814. Each shelf 814 is vertically offset from and above the bottom insert surface 722. The shelf 814 reduces in size as the shelf 814 extends towards the center of the bottom insert surface 722. The shelves 814 assist in supporting the bushing 712 and provide a hard stop to an anchor 904 (FIG. 9A) disposed on the bottom of the bushing 712. The shelf 814 is not present in portions of the bottom insert surface 722 disposed directly inward of the grooves 808. A plurality of wedge securing openings 812 are disposed through the bottom insert surface 722 and towards the bottom surface 804 of the insert 710. The wedge securing openings 812 are configured to receive one of the fasteners 724 for securing a respective wedge 714.

FIG. 8B is a plan view of the insert 710 of the bushing assembly 706. The insert 710 as described herein includes three grooves 808 evenly spaced around the cylindrical sidewall 810. One of the wedge securing openings 812 is disposed radially inward of each of the grooves 808, such that each wedge securing opening 812 is disposed between one of the grooves 808 and the insert fastener opening 720. Each of the shelves 814 includes an inner stepped surface 815. The inner stepped surface 815 is the surface between the shelf 814 and the bottom insert surface 722.

FIG. 9A is an isometric view of the bushing 712 of the bushing assembly 706, according to one or more embodiments. The bushing 712 includes a top surface 906, a bottom surface 908, and an outer sidewall 902 connecting the top surface 906 and the bottom surface 908. The outer sidewall 902 includes an angled surface 914 and a vertical surface 912. The angled surface 914 extends from the top surface 906 and towards the bottom surface 908. The angled surface 914 is angled such that the bushing 706 increases in thickness as the angled surface 914 extends towards the bottom surface 908. The vertical surface 912 extends between the angled surface 914 and the bottom surface 908. The vertical surface 912 is normal to the bottom surface 908.

As shown in FIG. 9B, the top surface 906 is roughly triangular in shape with curved corners. The top surface 906 is an equilateral triangle with curved corners. The bottom surface 908 has a similar shape as the top surface 906, but the length of the sides of the bottom surface 908 are longer. The shape of the top surface 906 and the bottom surface 908 is similar to the outline of the outer sidewall 902. Each of the corners 910 of the outer sidewall 902 are curved as shown herein.

The anchor 904 is disposed from the bottom surface 908 of the bushing 712. The anchor 904 is a cylindrical protrusion and is configured to contact the inner stepped surface 815 when the bushing 712 has reached a maximum allowed offset in a horizontal direction. The bushing opening 726 is disposed through the top surface 906 of the bushing 712. The bushing opening 726 includes a tapered opening 916. The tapered opening 916 is disposed between the top surface 906 and the body of the bushing opening 726 and is configured to guide a securing pin or other securing means into the bushing opening 726.

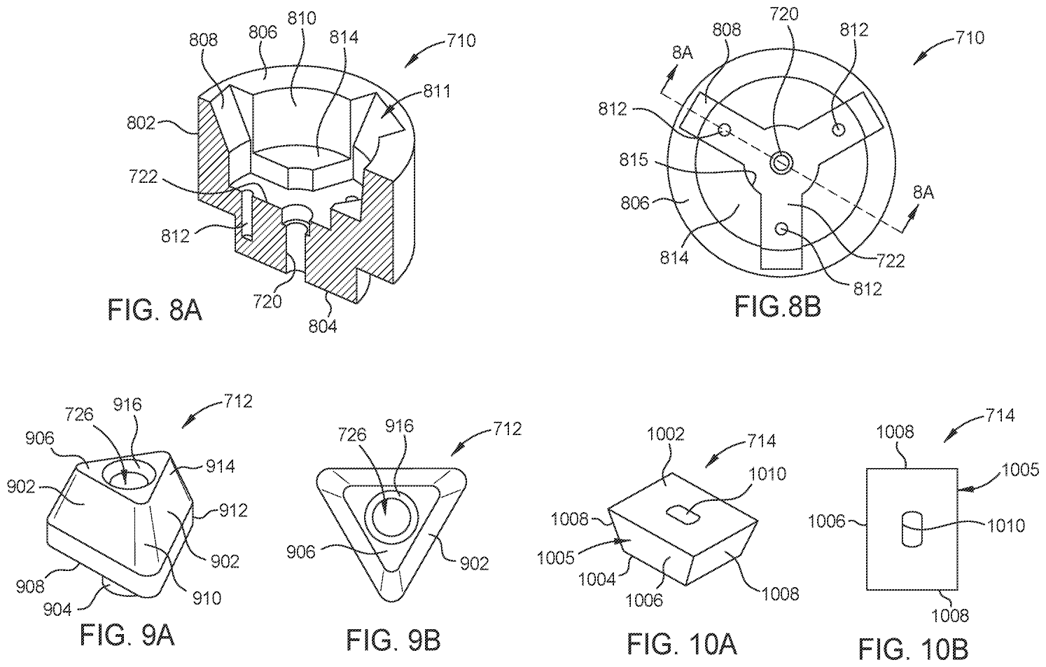

FIG. 10A is an isometric view of one of the wedges 714 of the bushing assembly 706, according to one or more embodiments. Each wedge 714 includes a top surface 1002, a bottom surface 1004, and an outer sidewall 1005 disposed between the top surface 1002 and the bottom surface 1004. The top surface 1004 and the bottom surface 1004 are rectangular in shape and include an opening 1010 disposed therethrough. The opening 1010 extends from the top surface 1002 to the bottom surface 1004.

The outer sidewall 1005 includes a first set of sidewalls 1006 and a second set of sidewalls 1008. The first set of sidewalls 1006 are disposed normal to the top surface 1002 and the bottom surface 1004. The first set of sidewalls 1006 are disposed on opposite sides of the wedge 714. The first set of sidewalls 1006 are trapezoids, such that the bottom surface 1004 is smaller than the top surface 1002 in at least one dimension. The second set of sidewalls 1008 are rectangular in shape and extend between the top surface 1002 and the bottom surface 1004. The second set of sidewalls 1008 are disposed on opposite sides of the wedge 714, such that the second set of sidewalls 1008 are separated on either side by one of the first sidewalls 1006. The second set of sidewalls 1008 are disposed at an angle other than normal to the top surface 1002 and the bottom surface 1004. The second set of sidewalls 1008 are angled such that as the second set of sidewalls 1008 extends towards the bottom surface 1004, the width of the wedge 714 is decreased. As shown in FIG. 10B, the opening 1010 is disposed through the center of the top surface 1002. The opening 1010 may be a circular, oval, elliptical, or obround shape. The opening 1010 is configured to enable a fastener, such as one of the fasteners 724 to pass therethrough. The opening 1010 having a non-circular shape enables a fastener passing therethrough to be angled or adjusted in at least one direction. The slanted second set of sidewalls 1008 enables the wedge 714 to slide along the outer sidewall 902 of the bushing 712 and adjust the position of the bushing 712.

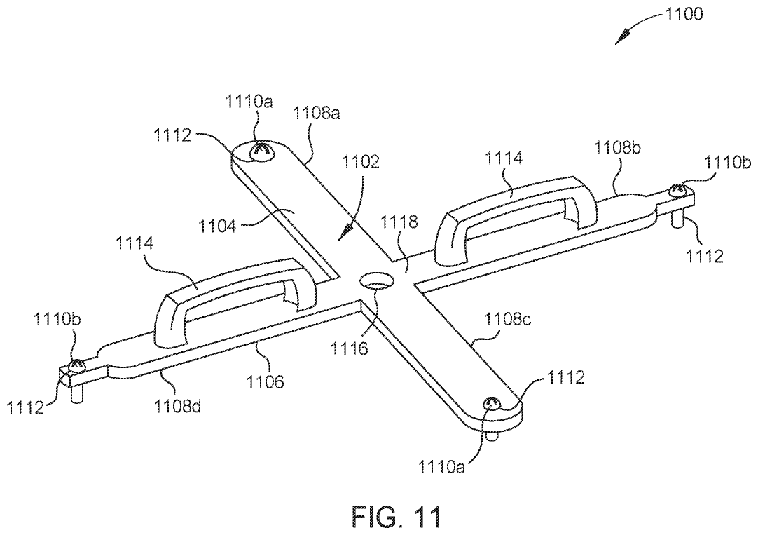

FIG. 11 is an isometric view of a bushing alignment assembly 1100, according to one or more embodiments. The bushing alignment assembly 1100 assists in proper alignment and calibration of each of the bushing assemblies 706. The bushing alignment assembly 1100 includes a central portion 1118 and a plurality of arms 1102 extending outward from the central portion 1118. The plurality of arms 1102 includes a first arm 1108a, a second arm 1108b, a third arm 1108c, and a fourth arm 1108d. The first arm 1108a and the third arm 1108c are opposite and similar to each other. The second arm 1108b and the fourth arm 1108d are also opposite and similar.

A reference opening 1116 is disposed through the central portion 1118. The reference opening 1116 is disposed through the top surface 1104 and the bottom surface 1106 of the bushing alignment assembly 1100. The bushing alignment assembly 1100 includes one or more handles 1114 coupled to the top surface 1104. The one or more handles 1114 includes two handles 1114. One handle 1114 is disposed on top of the second arm 1108b and a second handle 1114 is disposed on top of the fourth arm 1108d.

Both the first arm 1108a and the third arm 1108c include a holding pin 1110a disposed within a pin opening 1112 at an end of the first arm 1108a and the third arm 1108c, respectively. The pin openings 1112 are disposed through a portion of the arms 1108a, 1108c distal from the central portion 1118. The holding pin 1110a is configured to contact the upper module surface 211 and balance the bushing alignment assembly 1100. A pin opening 1112 is also formed through an end of each of the second arm 1108b and the fourth arm 1108d distal to the central portion 1118. The pin openings 1112 formed through the second arm 1108b and the fourth arm 1108d include a positioning pin 1110b disposed therein. The positioning pin 1110b is configured to be inserted into the bushing opening 727 of each of the bushing assemblies 706. The positioning pin 1110b is longer than the holding pin 1110a. The positioning pin 1110b extends past the bottom surface 1106 of the bushing alignment assembly 1100. In some embodiments, at least one of the holding pins 1110a may be a positioning pin 1110b when there are three or more bushing assemblies 706, such that there are three or four positioning pins 1110b disposed within the bushing alignment assembly 1100.

The bushing alignment assembly 1100 is configured to have the positioning pins 1110b inserted into one or more bushing assemblies 706 while the holding pins 1110a are configured to balance the bushing alignment assembly 1100. The reference opening 1116 is configured to receive a guide rod or other component (not shown) which is designed to be aligned with a central portion of one of the substrate support chucks 391. Alternatively, the reference opening 1116 may act as a viewing port and the bushing assemblies 706 are calibrated so the reference opening 1116 is aligned with the central portion of one of the substrate support chucks 391. Each of the bushing assemblies 706 are calibrated separately to adjust the positioning of the bushing alignment assembly 1100. The arms 1108a-d do not fully cover each of the bushing assemblies 706 while the bushing alignment assembly 1100 is being utilized. Not fully covering each of the bushing assemblies 706 enables calibration tools, such as a wrench or screwdriver, to be threaded around the bushing alignment assembly 1100 and the location of each wedge 714 to be adjusted.

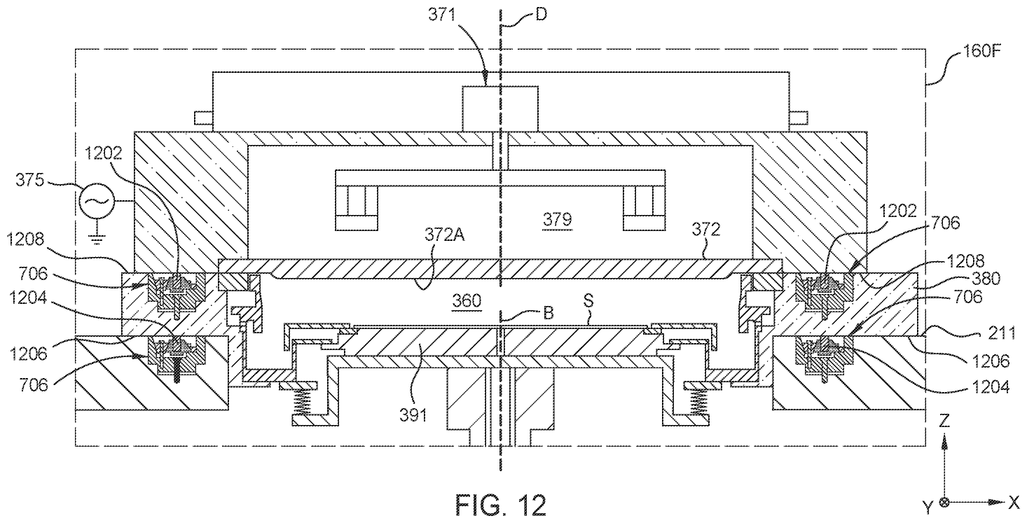

FIG. 12 is a cross-sectional view of a process station 160F within the processing module 150 of FIGS. 3A-3C. The process station 160F includes bushing assemblies 706 within the upper module surface 211 and within a top surface 1208 of the process kit assembly 380. The bushing assemblies 706 within the upper module surface 211 assist in placement of the process station 160F, while the bushing assemblies 706 within the top surface 1208 of the process kit assembly 380 assist in placement of the source assembly 370. The process station 160F may have placement pins 1204 disposed on a bottom surface 1206 thereof to secure the process station 160F to the upper module surface 211. Similarly, the bottom surface of the source assembly 370 includes source placement pins 1202.

The placement pins 1204 extend from the bottom surface 1206 of the process station 160F and into a set of bushing assemblies 706. The placement pins 1202 extend from the bottom surface of the source assembly 370 and into a set of bushing assemblies 706 disposed within the process kit assembly 380. Aligning the bushing assemblies 706 disposed on the top surface 1208 of the process kit assembly 380 centers the magnetron assembly 371 with the rest of the process station 160F. Aligning the bushing assemblies 706 disposed on the upper module surface 211 enables the source axis D to be aligned with the lift assembly axis B.

### Alignment and Calibration Methods

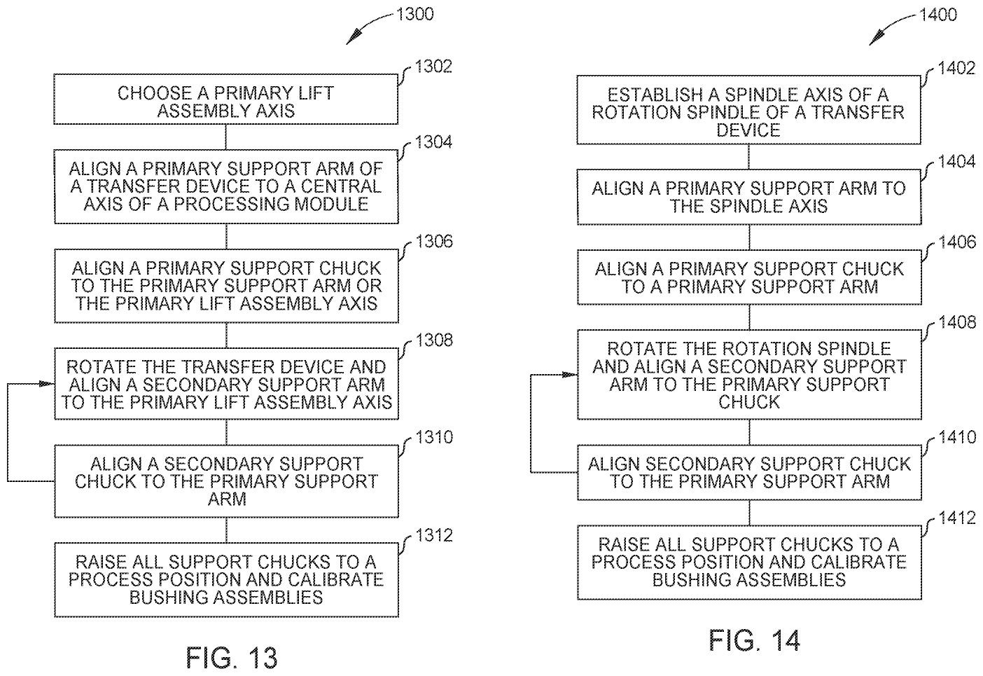

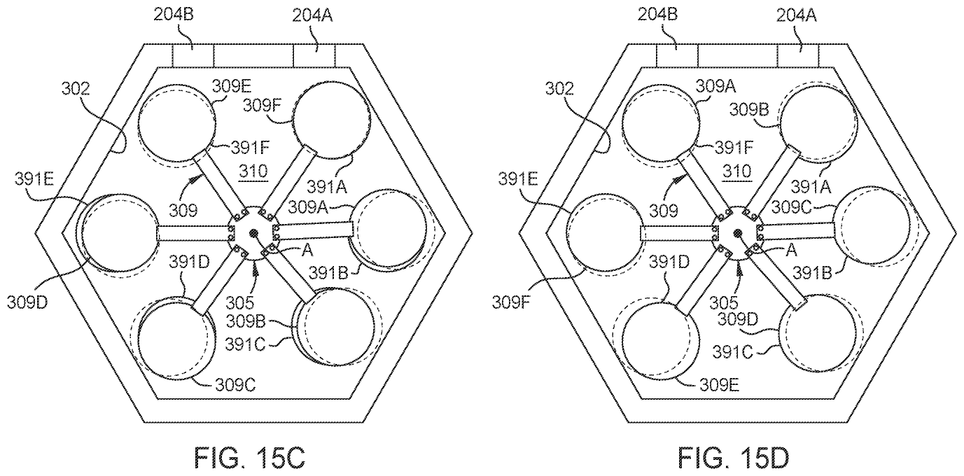

FIG. 13 depicts a method 1300 of aligning the support arms 309A-309F of the transfer device 155 and the substrate support chucks 391A-391F of the processing modules 160A-160F of FIGS. 3A-3C, according to one or more embodiments. The method 1300 is illustrated in FIGS. 15A-15D. As shown in FIG. 15A, each support arm 309 is misaligned with each corresponding substrate support chuck 391A-391F. There is one support arm 309A-309F corresponding to each substrate support chuck 391A-391F. The location of each of the process stations 160A-160F may be also misaligned with either or both of the corresponding support arms 309A-309F and the substrate support chucks 391A-391F.

During the method 1300, a primary lift assembly axis is chosen during an operation 1302. The primary lift assembly axis may be any one of the lift assembly axes B. In the embodiment of FIGS. 15A-15D, the primary lift assembly axis is the lift assembly axis B of the sixth process station 160F. After or concurrent to the operation 1302, a primary support arm, such as a sixth support arm 309F of the transfer device 155, is aligned with a central axis A of the processing module 150 during an operation 1304.

After the operations 1302 and 1304, a primary support chuck, such as the sixth support chuck 391F, is aligned with the primary support arm or the primary lift assembly axis during another operation 130B. In embodiments described herein, the primary support chuck is aligned to the primary lift assembly axis and the primary support arm is aligned with the primary support chuck and the primary lift assembly axis. The alignment of the primary support chuck to the primary support arm is illustrated in FIG. 15B.

Once the primary support chuck and the primary support arm are aligned they are locked into an aligned position. Adjusting and aligning the primary support chuck and the primary support arm includes adjusting fasteners at the base of the primary support arm as described with reference to FIGS. 6A-6C. The adjusting and aligning the primary support chuck includes adjusting fasteners attached to the lift assembly as described with reference to FIGS. 5A-5B. After locking the relative positions of the primary support chuck and the primary support arm, the transfer device 155 is rotated during an operation 1308. The rotation of the transfer device 155 brings a secondary support arm over the primary support chuck. The secondary support arm, such as the fifth support arm 309E, is then aligned with the primary lift assembly axis. The rotation of the transfer device 155 also positions the primary support arm over a secondary support chuck, such as the first support chuck 391A. During an operation 1310, the secondary support chuck is aligned with the primary support arm. FIG. 15C illustrates the processing module 150 after a first iteration of the operation 1308 and the operation 1310 are completed, such that the fifth support arm 309E is aligned with the sixth support chuck 391F and the first support chuck 391A is aligned with the sixth support arm 309F.

The operations 1308 and 1310 of aligning the secondary support arm to the primary lift assembly axis and aligning the secondary support chuck to the primary support arm may be looped until each of the support arms 309A-F and the support chucks 392A-F are aligned as shown in FIG. 15D. Aligning each of the support arms 309A-F and the support chucks 392A-F reduces error between handoff of substrates from the support chucks 392A-F to the support arms 309A-F and vice versa.

After each of the support arms 309A-F and the support chucks 392A-F are aligned, the support chucks 392A-F are raised to a process position as shown in FIG. 3A during an operation 1312. While the support chucks 392A-F are in the process position, bushing assemblies, such as the bushing assemblies 706, are calibrated. Calibrating the bushing assemblies enables each of the process stations 160A-F to be aligned with a corresponding support chuck 392A-F. The bushing assemblies may be calibrated using the bushing alignment assembly 1100 before placement of each of the process stations 160A-F onto the processing module 150.

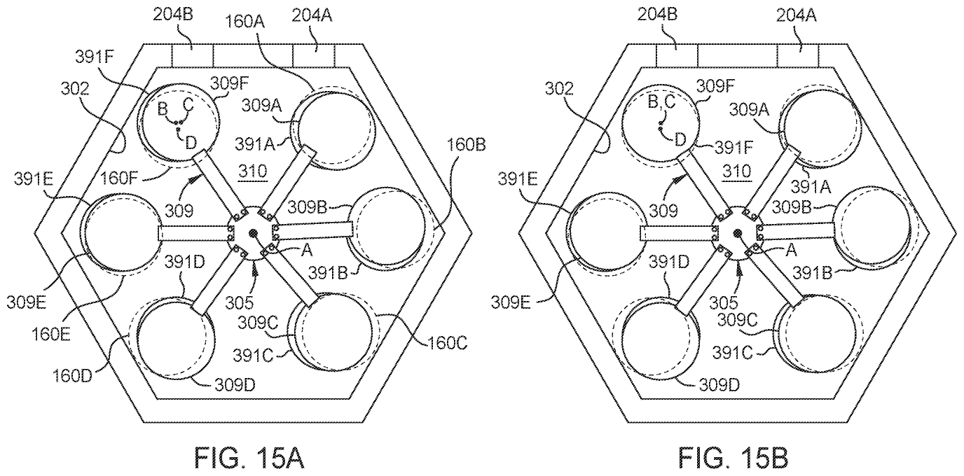

FIG. 14 depicts a second method 1400 of aligning the support arms 309A-309F of the transfer device 155 and the substrate support chucks 391A-391F of the processing modules 160A-160F of FIGS. 3A-3C, according to one or more embodiments. During the method 1400, a spindle axis is established during an operation 1402. The spindle axis is the central axis A of the rotation spindle 306 and therefore is the axis about which the transfer device 155 rotated.

Once the spindle axis is established, a primary support arm, such as the sixth support arm 309F, is aligned with respect to the spindle axis during an operation 1404. Aligning the sixth support arm 309F with respect to the spindle axis fixes the position of the sixth support arm 309F relative to the transfer device 155. A center axis passing through the sixth support arm 309F may be aligned with respect to and pass through the spindle axis. After alignment of the primary support arm with respect to the spindle axis, a primary support chuck is aligned with the primary support arm during an operation 1406. The primary support chuck may be the sixth support chuck 391F. After alignment of the primary support chuck and the primary support arm, the processing module 150 may be similar to the processing module 150 of FIG. 15B. Once the primary support chuck and the primary support arm are aligned they are locked into an aligned position. Adjusting and aligning the primary support chuck and the primary support arm includes adjusting fasteners at the base of the primary support arm as described with reference to FIGS. 6A-6C. The adjusting and aligning the primary support chuck includes adjusting fasteners attached to the lift assembly as described with reference to FIGS. 5A-5B.

After alignment of the primary support chuck to the primary support arm, the rotation spindle is rotated about the spindle axis during an operation 1408. During the operation 1408 a secondary support arm, such as the fifth support arm 309E is aligned with the primary support chuck. A secondary support chuck, such as the first support chuck 391A, is aligned with the primary support during an operation 1410. The alignment operations of the operation 1408 and the operation 1410 may be performed simultaneously or subsequent to each other. After one iteration of the operation 1408 and the operation 1410, the processing module 150 is similar to that shown in FIG. 15C.

The operation 1408 and the operation 1410 are looped to align each of the secondary support arms 309A-309E and the secondary support chucks 309A-309E. Once all of the support arms 309A-309F and the support chucks 309A-309F are aligned, the processing module 150 is similar to that shown in FIG. 15D. After each of the support arms 309A-F and the support chucks 392A-F are aligned, the support chucks 392A-F are raised to a process position as shown in FIG. 3A during an operation 1412. The operation 1412 is similar to the operation 1312.

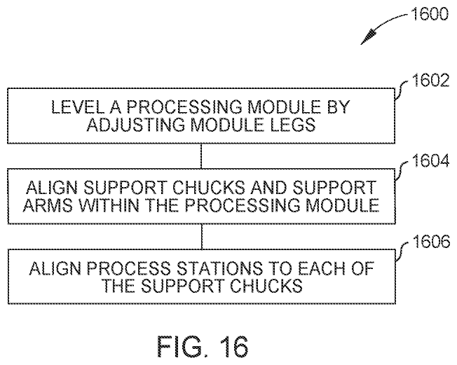

FIG. 16 depicts a method 1600 of correcting alignment within the processing module 150 of FIGS. 3A-3C, according to one or more embodiments. The method 1600 includes leveling the processing module 150 during an operation 1602. Leveling is performed by adjusting the support legs 404a-404c of the processing module 150. As described herein, the second support leg 404b and the third support leg 404c are adjusted to raise or lower portions of the processing module 150 distal from the portion connected to a transfer chamber or an intermediate robot chamber.

After leveling the processing module 150, the support chucks 309A-309F and the support arms 309A-309F are aligned using one of the methods 1300 or 1400 described herein. The alignment of the support arms 309A-309F and the support chucks 309A-309F is performed during an operation 1604. After the operation 1604, each process station 160A-160F is aligned with one of the support chucks 209A-309F during an operation 1606. The alignment of each process station 160A-160F is performed by calibrating the adjustable bushing assemblies 706.

While the foregoing is directed to embodiments of the present disclosure, other and further embodiments of the disclosure may be devised without departing from the basic scope thereof, and the scope thereof is determined by the claims that follow.

What is claimed is:

1. A processing module for semiconductor processing, comprising:
a transfer device disposed within a transfer region of the processing module, the transfer device comprising:
a central hub having a central axis disposed therethrough; and
a plurality of support arms adjustably coupled to the central hub and configured to be rotated around the central axis;
a support chuck assembly disposed at least partially within the transfer region, the support chuck assembly comprising:
a support chuck having a substrate support surface;
a pedestal shaft coupled to the support chuck; and
a lift assembly coupled to the pedestal shaft, the lift assembly comprising:
a module attachment plate;
a static connection connecting the module attachment plate to a bottom surface of the processing module; and
two or more adjustable connections disposed between the module attachment plate and the bottom surface of the processing module, the two or more adjustable connections configured to be adjusted to change the orientation of the support chuck assembly relative to the transfer device.

2. The processing module of claim 1, wherein the central hub comprises one or more regions with one or more openings disposed therethrough, each of the one or more regions configured to receive a base of one of the plurality of support arms.

3. The processing module of claim 1, wherein the lift assembly further comprises:
a bellows disposed around a portion of and coupled to the pedestal shaft; and
an opening formed through the module attachment plate, the pedestal shaft disposed through the opening.

4. The processing module of claim 1, wherein each support arm of the plurality of support arms comprises:
a base;
an arm shaft coupled to the base at a first end of the arm shaft; and
a head coupled to a second end of the arm shaft, the head configured to support portions of a substrate.

5. The processing module of claim 4, wherein the head further comprises:
a first grasper comprising a first ledge;
a second grasper comprising a second ledge; and
a ceiling vertically offset from the first grasper and the second grasper, wherein a first angled surface connects the first ledge to the ceiling and a second angled surface connects the second ledge to the ceiling.

6. The processing module of claim 5, wherein the first angled surface is disposed at an angle of about 110 degrees to about 135 degrees with respect to the first ledge and the second angled surface is disposed at the angle with respect to the second ledge.

7. The processing module of claim 1, wherein the static connection is configured to act as a pivot point around which the lift assembly is rotated.

8. The processing module of claim 7, wherein the two or more adjustable connections are disposed on an opposite side of an opening through the module attachment plate with respect to the static connection.

9. The processing module of claim 8, wherein each of the two or more adjustable connections include a spring disposed between the module attachment plate and the bottom surface of the processing module to maintain a spring force separating the module attachment plate and the bottom surface of the processing module.

10. A processing module for semiconductor processing, comprising:
a plurality of walls defining a transfer region;
a plurality of process stations coupled to one or more of the plurality of walls and in fluid communication with the transfer region;
a support chuck assembly disposed at least partially within the transfer region, the support chuck assembly comprising:
a support chuck having a substrate support surface;
a pedestal shaft coupled to the support chuck; and
a lift assembly coupled to the pedestal shaft, the lift assembly comprising:
a module attachment plate;
a static connection connecting the module attachment plate to a lower wall of the plurality of walls; and
two or more adjustable connections disposed between the module attachment plate and the lower wall, the two or more adjustable connections configured to be adjusted to change the orientation of the support chuck assembly; and
two or more adjustable bushings disposed between a portion of each of the process stations and the one or more of the plurality of walls, the adjustable bushings configured to enable adjustment of a location of a first process station of the plurality of process stations relative to the support chuck assembly.

11. The processing module of claim 10, wherein the two or more adjustable bushings comprise:
an insert disposed in a top surface of the one or more of the plurality of walls;
a bushing disposed inside of the insert; and
two or more wedges disposed around the bushing and between the insert and the bushing, the two or more wedges configured to be moved to adjust a location of the bushing within the insert.

12. The processing module of claim 11, wherein the two or more wedges are connected to the insert using one or more fasteners.

13. The processing module of claim 11, wherein the two or more wedges comprises three wedges.

14. The processing module of claim 10, wherein the lower wall of the processing module is coupled to a lower supporting structure, the lower supporting structure comprising a first support leg and two or more adjustable second support legs.

15. The processing module of claim 14, wherein the head further comprises:
a first grasper comprising a first ledge;
a second grasper comprising a second ledge; and
a ceiling vertically offset from the first grasper and the second grasper, wherein a first angled surface connects the first ledge to the ceiling and a second angled surface connects the second ledge to the ceiling, the first angled surface disposed at an angle of about 110 degrees to about 135 degrees with respect to the first ledge and the second angled surface disposed at the angle with respect to the second ledge.

16. The processing module of claim 15, wherein the first angled surface and the second angled surface have a surface roughness of less than about Ra 15 μin.

17. The processing module of claim 10, the two or more adjustable bushings around each of the process stations comprises two adjustable bushings configured to engage with a portion of each process station of the plurality of process stations.

18. A processing module for semiconductor processing, comprising:
a transfer device disposed within a transfer region of the processing module, the transfer device comprising:
a central hub having a central axis disposed therethrough; and
a plurality of support arms adjustably coupled to the central hub and configured to be rotated around the central axis and carry a substrate;
a support chuck assembly disposed at least partially within the transfer region of the processing module, the support chuck assembly comprising:
a support chuck having a substrate support surface;
a pedestal shaft coupled to the support chuck; and
a lift assembly coupled to the pedestal shaft, the lift assembly comprising:
a module attachment plate;
a static connection connecting the module attachment plate to a bottom surface of the processing module; and
two or more adjustable connections disposed between the module attachment plate and the bottom surface of the processing module, the two or more adjustable connections configured to be adjusted to change the orientation of the support chuck assembly;
a plurality of process stations coupled to an upper surface of the processing module and in fluid communication with the transfer region; and
two or more adjustable bushings disposed between a portion of each of the process stations and the upper surface, the adjustable bushings configured to enable adjustment of a location of a first process station of the plurality of process stations relative to the support chuck assembly.

19. The processing module of claim 18, wherein the static connection is configured to act as a pivot point around which the lift assembly is rotated and the two or more adjustable connections each comprise:
a spring disposed between the module attachment plate and the bottom surface of the processing module; and
a separation rod disposed through the module attachment plate and configured to have an adjustable first length on a top side of the module attachment plate.

20. The processing module of claim 18, wherein the two or more adjustable bushings comprise:
an insert disposed in the upper surface of the processing module;
a bushing disposed inside of the insert; and
two or more wedges disposed around the bushing and between the insert and the bushing, the two or more wedges configured to be moved to adjust a location of the bushing within the insert.
